(19) United States
(12) Patent Application Publication
(10) Pub. No.: US 2014/0122973 A1
(43) Pub. Date: May 1, 2014

(54) DISTRIBUTED CODEWORD PORTIONS

(71) Applicant: Ravi H. Motwani, San Diego, CA (US)

(72) Inventor: Ravi H. Motwani, San Diego, CA (US)

(21) Appl. No.: 13/992,851

(22) PCT Filed: Mar. 12, 2012
(86) PCT No.: PCT/US12/28763

§ 371 Date: Jun. 10, 2013

(51) Int. Cl. H03M 13/11; G06F 11/10

(52) U.S. Cl. CPC H03M 13/1105; G06F 11/1008
USPC 714/773; 714/763

(57) ABSTRACT

Embodiments of the present disclosure describe apparatus, methods, computer-readable media and system configurations for dividing error correcting code (“ECC”) codewords into portions and storing the portions among multiple memory components. For example, a device may include non-volatile memory (“NVM”) including m die. A memory controller may be configured to store portions of an ECC codeword among the m die. In various embodiments, a memory controller and/or an iterative decoder such as a low-density parity-check (“LDPC”) decoder may be configured to decode ECC codewords based at least in part on reliability metrics associated with the m die. Other embodiments may be described and/or claimed.

### FIELD

Embodiments of the present disclosure relate generally to the field of data processing, and more particularly, to use of data encoding to protect data stored in non-volatile memory.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. Unless otherwise indicated herein, the approaches described in this section are not prior art to the claims in the present disclosure and are not admitted to be prior art by inclusion in this section.

A memory controller of non-volatile memory (“NVM”) may use a variety of data encoding/decoding techniques to handle bit errors and recover data. For example, data may be encoded as one or more codewords, e.g., as low-density parity-check (“LDPC”) codewords. The memory controller may include an iterative decoder, such as an LDPC decoder, configured to decode the codewords.

Some types of codewords, such as LDPC-encoded codewords, may include an original message and associated parity data. A non-binary iterative decoder (e.g., an LDPC decoder) may process the codeword multiple times during decoding. Symbols and soft information (e.g., associated probabilities that the symbols are correct) may be passed between variable nodes and check nodes corresponding to relationships between the variable nodes. Each iteration may bring the codeword closer to the original message.

NVM may include a plurality of physical components, such as a plurality of die. In current devices, a codeword may be stored on a single die. However, if that die has a particularly low reliability, e.g., due to a high raw bit error rate (“RBER”), then a probability of failure during decoding of the codeword may be particularly high.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates example codewords stored among multiple die, in accordance with various embodiments.

FIG. 2 depicts an example of how an iterative decoder may utilize raw bit error rates of die to decode codewords, in accordance with various embodiments.

FIG. 3 depicts a voltage distribution of two levels used for storing one bit of information, to demonstrate how hard decisions may be made and soft information may be generated, in accordance with various embodiments.

FIG. 4 depicts example RBER distributions that may result from storing low-density parity-check (“LDPC”)-encoded codewords among multiple die of memory versus storing LDPC codewords on single die, in accordance with various embodiments.

FIG. 5 schematically depicts an example method, in accordance with various embodiments.

FIG. 6 schematically depicts an example computing device, in accordance with various embodiments.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” may refer to, be part of, or include an Application Specific Integrated Circuit (“ASIC”), an electronic circuit, a processor (shared, dedicated, or group) and/or memory (shared, dedicated, or group) that execute one or more software or firmware programs, a combinational logic circuit, and/or other suitable components that provide the described functionality. As used herein, “computer-implemented method” may refer to any method executed by one or more processors, a computer system having one or more processors, a mobile device such as a smart phone (which may include one or more processors), a tablet, laptop computer, a set-top box, a gaming console, and so forth.

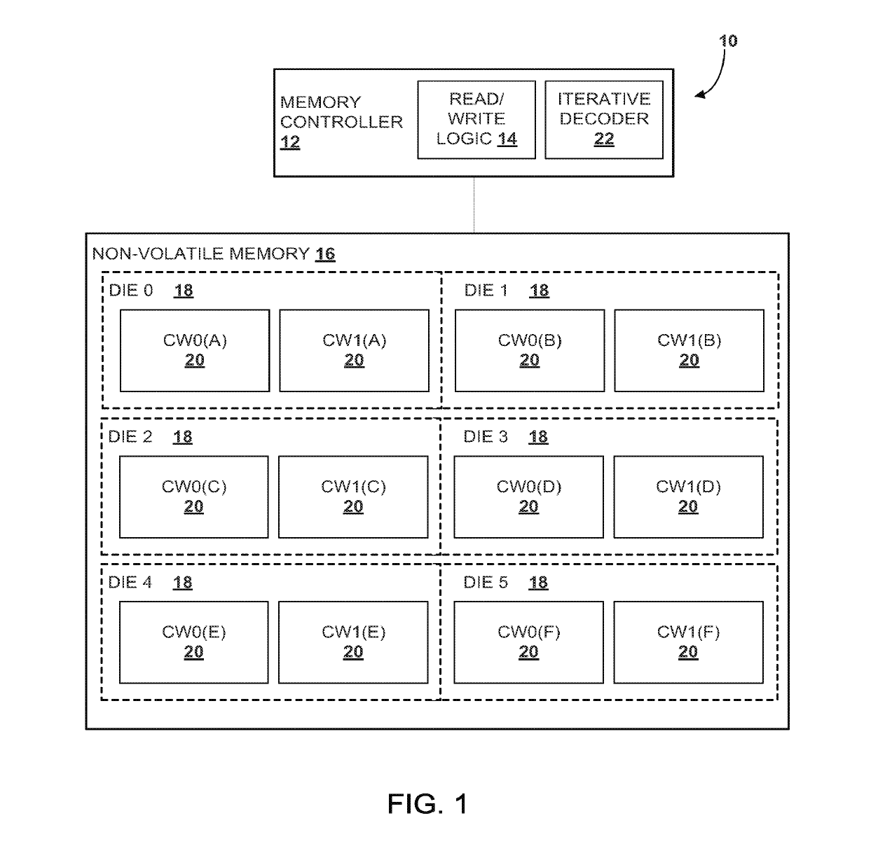

Referring now to FIG. 1, an example a memory controller 12 with read/write logic 14 may be operably coupled to non-volatile memory (“NVM”) 16. In various embodiments, memory controller 12 may be implemented using hardware (e.g., a digital circuit). In some embodiments, NVM 16 may be NAND flash memory. In various embodiments, NVM 16 may be other types of memory, such as ferroelectric random-access memory (“FeTRAM”), nanowire-based NVM, phase change memory (“PCM”), PCM with switch (“PCMS”), and so forth.

The term “memory apparatus” may be used herein to refer to any device having a memory controller (e.g., 12) and NVM (e.g., 16). In some embodiments, a memory controller and NVM may be packaged together into a memory apparatus in the form of an integrated circuit that may be installed into a computing device such as a tablet or mobile telephone. In various embodiments, NVM 16 may include various numbers of die 18. In the example of FIG. 1, NVM 16 includes six die 18, DIE 0-5. More or fewer die 18 may be included in NVM 16. Six die 18 are included in FIG. 1 for illustrative purposes only.

A message (or portion thereof) encoded as a codeword may be stored on a single memory component such as a die 18. However, if this memory component fails, it may be difficult to recover the data represented by the codeword. For example, a random variable x may be said to have a lognormal distribution with mean μ if log(x)-μ has a Gaussian distribution, so that a probability distribution function (“pdf”) of the lognormal distribution may be given by:

$${f}_{x} ( x ; μ , σ ) = \frac{1}{x σ \sqrt{2 π}} {e}^{- \frac{{( ln x - μ )}^{2}}{2 {σ}^{2}}} , x > 0$$

Thus, in example memory apparatus, a few die may have low raw bit error rates (“RBER”) and a minor fraction of die may have high RBERs. For whole codewords stored on the die with high RBERs, the probability of a fatal error during decoding may be more likely. Accordingly, portions of codewords may be stored among multiple memory components such as die—a process which may be referred to as “diversity combining”—to gain various benefits obtained from codeword diversity (i.e., codewords being divided and distributed among multiple components).

In various embodiments, codewords may be stored among multiple die 18, as shown in FIG. 1. Two codewords, CW0 and CW1, are shown stored in NVM 16. Rather than storing a codeword on a single die 18, each codeword is divided into six portions and stored in segments 20 of multiple die 18. For example, CW0 is split into CW0(A)-(F), which are stored in segments 20 of DIE 0-5. Likewise, CW1 is split into CW1(A)-(F), which are stored in segments 20 of DIE 0-5.

The example of FIG. 1 is for illustrative purposes only and is not meant to be limiting. Generally, a codeword may be divided into m portions and distributed among m die. For example, a codeword may be divided into two portions and stored among two die. As another example, a codeword may be divided into four portions and stored among four die. In various embodiments, a codeword may be divided into eight portions and stored among eight die.

In various embodiments, an iterative decoder 22 may be configured to receive as input m codeword portions from m die (e.g., six in FIG. 1) and decode the codeword using the m codeword portions and soft information associated with bits or groups of bits in each codeword portion. In various embodiments, such as that depicted in FIG. 1, iterative decoder 22 may be part of memory controller 12. In other embodiments, iterative decoder 22 may be separate from but operably coupled to an memory controller 12.

In various embodiments, “soft information” may refer to a likelihood that a bit or group of bits in a codeword portion is correct (e.g., a confidence level). In various embodiments, soft information may be expressed in logarithmic form. For single-bit, or “binary,” implementations, soft information may be expressed as log-likelihood ratios, or “LLR.” For multi-bit, or “non-binary,” implementations, soft information may be expressed as log density ratios, or “LDR.” In various embodiments, iterative decoder 22 may be a LDPC decoder, and the codewords (e.g., CW0, CW1) and/or their portions may be codewords encoded by an LDPC encoder (not shown).

In various embodiments, reliability metrics associated with m die may be used to generate the soft information that may be used as input to iterative decoder 22. For example, in various embodiments, reliability metrics associated with the m die may be RBERs. These RBERs may be used to generate soft information associated with data read from the m die.

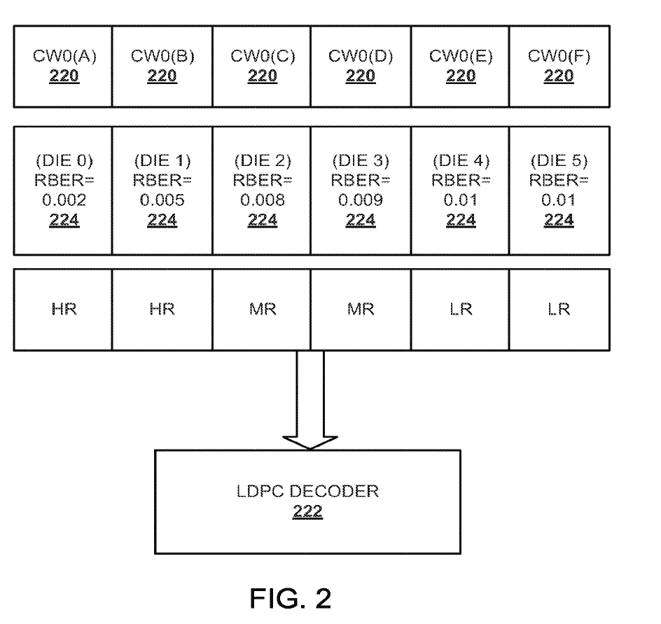

For example, and referring now to FIG. 2, six memory segments 220, each storing a portion of an LDPC codeword (CW0 of FIG. 1), may be located on six different die of NVM (DIE 0-5 of FIG. 1). Each die may have an associated reliability metric 224, which in FIG. 2 is a RBER. Starting from the left, a die with memory segment 220 storing CW0(A) has an associated RBER of 0.002. A die with memory segment 220 storing CW0(B) has an associated RBER of 0.005. A die with memory segment 220 storing CW0(C) has an associated RBER of 0.008. A die with memory segment 220 storing CW0(D) has an associated RBER of 0.009. Die with memory segments 220 storing CW0(E) and CW0(F) have associated RBERs of 0.01.

In various embodiments, an iterative decoder such as iterative decoder 22 in FIG. 1 may be configured to generate soft information associated with data received from one or more die (e.g., die 18 in FIG. 1) based at least in part on RBERs of the one or more die. In FIG. 2, for instance, an LDPC decoder 222 may generate soft information for each bit or group of bits in each received codeword portion by assigning potential probabilities (e.g., LLRs, LDRs) to each die based on the RBER of the die. LDPC decoder 222 may then decode portions of CW0 it receives from those die based at least in part on the assigned potential probabilities.

For example, in FIG. 2, DIE 0 and DIE 1 both have relatively low RBERs, 0.002 and 0.005, respectively. Thus, LDPC decoder 222 may consider them to be highly reliability (“HR”), and therefore may assign relatively high potential probabilities, such as {−16, −8, −3, +3, +8, +16}, to DIE 0 and DIE 1. In contrast, LDPC decoder 222 may assign “less confident” reliability values, such as {−5, −3, −1, +1, +3, +5}, to low reliability (“LR”) die like DIE 4 and DIE 5 in FIG. 2 that have higher RBERs (0.01). The sign of the potential probability or LLR may indicate whether the bit is a zero (positive) or a one (negative).

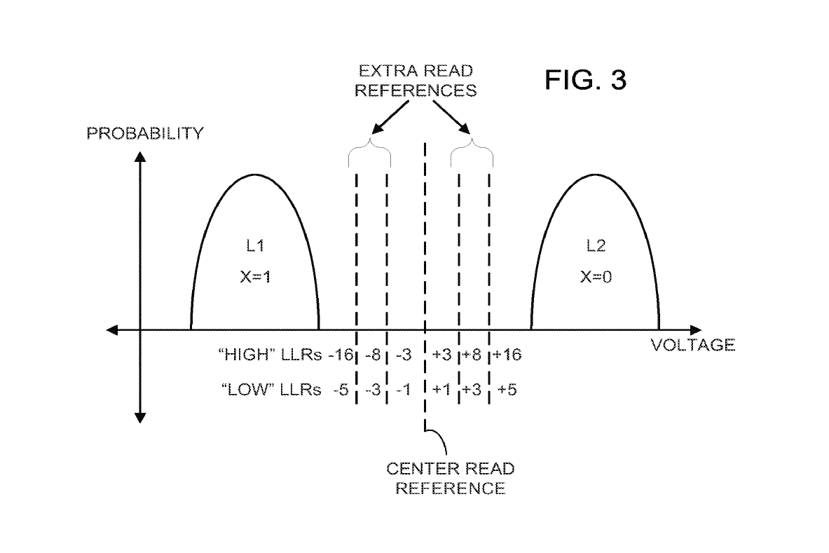

FIG. 3 depicts an example voltage distribution of a two-level, single-bit (X) memory cell, in which the horizontal axis represents a supply voltage and the horizontal axis represents a probability distribution. The “center read reference” voltage may be applied to the cell first to yield a “hard decision” about whether bit X is a one or zero.

Once the hard decision is made, corresponding soft information (e.g., probability that the hard decision is correct) may be generated. To generate soft information, “extra read reference” voltages may be applied, e.g., by a memory controller. These extra read reference supply voltages are represented by the dotted lines flanking the center read reference voltage in FIG. 3. Additionally, potential probabilities (e.g., LLRs, LDRs) may be assigned to the regions in between the extra read reference supply voltages. These potential probabilities may be based on, and in some embodiments, inversely proportional to, the RBER of the die. For instance, a high RBER/low reliability die may be assigned potential probabilities of relatively small magnitude, whereas a low RBER/high reliability die may be assigned potential probabilities of relatively large magnitude. In various embodiments, the soft information may be generated based on soft decisions resulting from the extra read reference supply voltages (e.g., which region) and corresponding probabilities (e.g., magnitude of confidence associated with the region). This may be better understood by way of examples in which “high” and “low” LLRS are assigned to the regions defined by the extra read reference voltages.

In FIG. 3, the series of “high” LLRs discussed above with regard to FIG. 2 are shown positioned within the regions defined by the extra read reference voltages. Assume application of the center read reference voltage indicates that the bit X=1. The far left extra read reference supply voltage may then be applied. If the far left extra read reference supply voltage yields a one, then an LLR of −16 may be assigned to the hard decision, which may indicate a high level of confidence that the bit X is indeed a one. However, if the far left extra read reference supply voltage yields a zero, then the next extra read reference supply voltage to the right may be applied. If the next extra read reference supply voltage yields a one, then an LLR of −8 may be assigned to the hard decision, indicating a medium level of confidence. However, if it yields a zero, then an LLR of −3 may be assigned to the hard decision, indicating a relatively low level of confidence.

Below the “high” LLRs in FIG. 3 are depicted the “low” LLRs that were discussed above with regard to FIG. 2. These low LLRs may be assigned to DIE 4 and DIE 5 in FIG. 2. When using these low LLRs (e.g., while decoding a codeword from DIE 4 or DIE 5), the soft information associated with the hard decision for the bit X may never be greater than +/−5, and could be as low as +/−1. This may indicate a lower level of confidence than when DIE 0 or 1 are decoded.

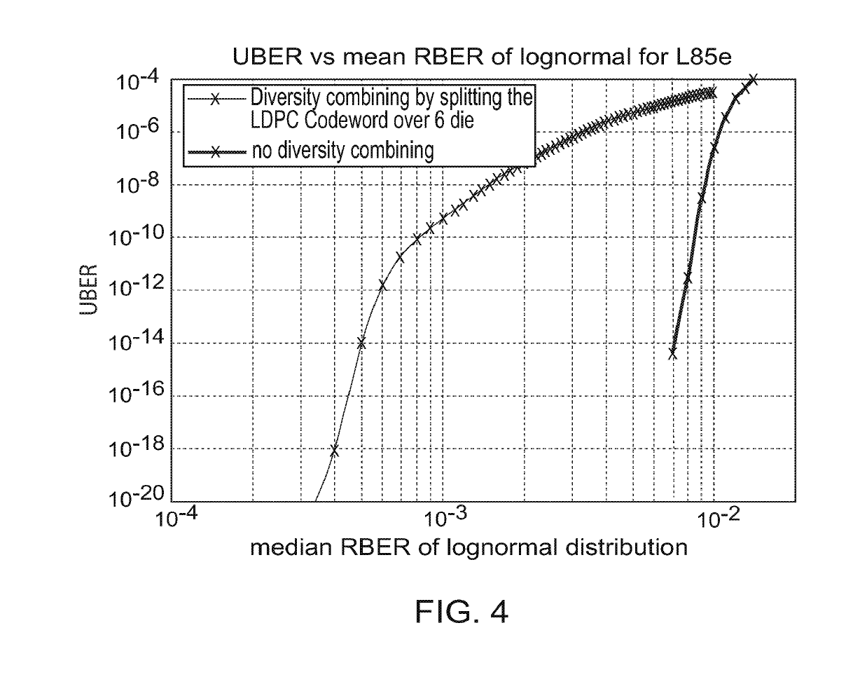

FIG. 4 depicts a chart showing example performance results comparing uncorrectable bit error rates (“UBER”) versus mean RBERs. In a first data set, each codeword is stored on a single die, which means there is no codeword diversity. In a second data set, diversity combining is achieved by splitting each LDPC codeword among six die. As can be seen in FIG. 4, gains on the order of 10× may be realized by distributing codewords among multiple memory components.

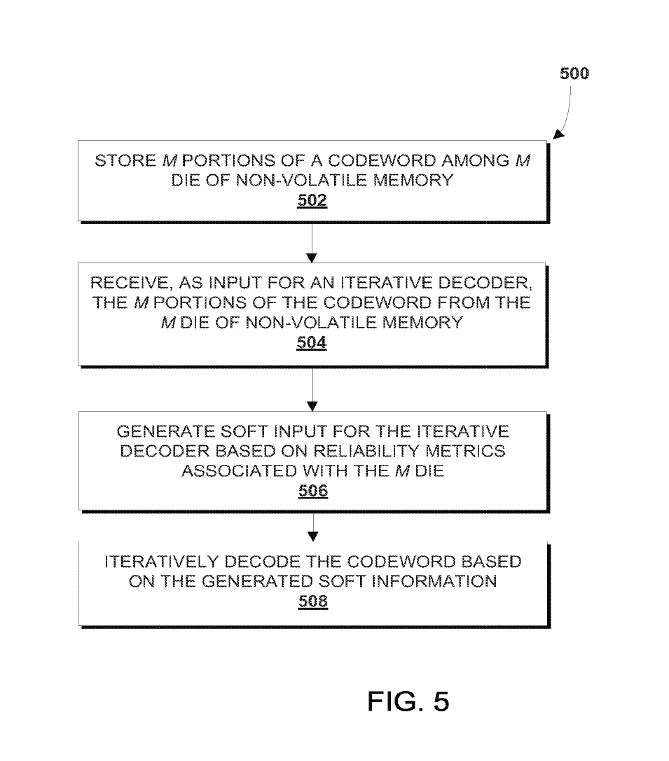

FIG. 5 depicts an example method 500 that may be implemented by a memory controller (e.g., memory controller 12 in FIG. 1) and/or an iterative decoder (e.g., iterative decoder 22 of FIG. 1, LDPC decoder 222 in FIG. 2) associated with a memory controller. At block 502, m portions of a codeword such as an LDPC codeword may be stored among m die of non-volatile memory (e.g., NAND flash).

At block 504, the m portions of the codeword may be received, e.g., as input for an iterative decoder (e.g., iterative decoder 22 in FIG. 1 or LDPC decoder 222 in FIG. 2), from the m die of the non-volatile memory. For example, m portions of the codeword may be read from m die by a read/write logic (e.g., 14) and passed to an iterative decoder (e.g., 22, 220).

At block 506, reliability metrics associated with the m die may be used to generate soft information, e.g., as input for the iterative decoder. In various embodiments, the soft information may include potential probabilities (e.g., {−16, −8, −3, +3, +8, +16} or {−5, −3, −1, +1, +3, +5}) that are based at least in part on the reliability metrics of the m die, as described above.

Using the m received codeword portions and soft information, at block 508, a memory controller (e.g., memory controller 12 in FIG. 1) and/or an iterative decoder (e.g., iterative decoder 22 in FIG. 1 or LDPC decoder 222 in FIG. 2) may iteratively decode the codeword.

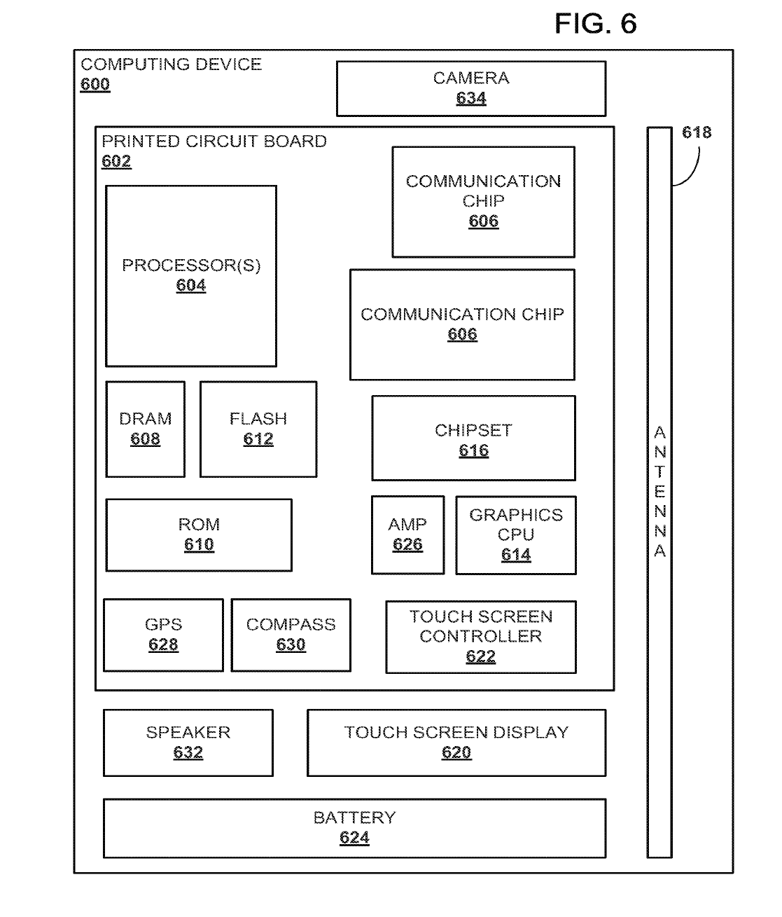

FIG. 6 illustrates a computing device 600 in accordance with various embodiments. The computing device 600 houses a printed circuit board (“PCB”) 602. The PCB 602 may include a number of components, including but not limited to a processor 604 and at least one communication chip 606. The processor 604 may be physically and electrically coupled to the PCB 602. In various embodiments, the at least one communication chip 606 may also be physically and electrically coupled to the PCB 602. In further implementations, the communication chip 606 may be part of the processor 604.

Depending on its applications, computing device 600 may include other components that may or may not be physically and electrically coupled to the PCB 602. These other components include, but are not limited to, volatile memory (e.g., dynamic random access memory 608, also referred to as “DRAM”), non-volatile memory (e.g., read-only memory 610, also referred to as “ROM”), flash memory 612, a graphics processor 614, a digital signal processor (not shown), a crypto processor (not shown), a chipset 616, an antenna 618, a display (not shown), a touch screen display 620, a touch screen controller 622, a battery 624, an audio codec (not shown), a video codec (not shown), a power amplifier 626, a global positioning system (“GPS”) device 628, a compass 630, an accelerometer (not shown), a gyroscope (not shown), a speaker 632, a camera 634, and a mass storage device (such as a hard disk drive, a solid state drive, a compact disk (“CD”), digital versatile disk (“DVD”)) (not shown), and so forth.

The communication chip 606 may enable wired and/or wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, Long Term evolution (“LTE”), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 may include an integrated circuit die packaged within the processor 604. In various embodiments, the integrated circuit die of the processor 604 may include one or more devices, such as transistors or metal interconnects, that are formed to facilitate distributed storage of codewords and iterative decoding of distributed codewords using one or more techniques described herein. The term “processor” may refer to any device or portion of a device that processes electronic data from registers and/or memory to transform that electronic data into other electronic data that may be stored in registers and/or memory.

The communication chip 606 may also include an integrated circuit die packaged within the communication chip 606. In various embodiments, the integrated circuit die of the communication chip 606 may include one or more devices, such as transistors or metal interconnects, that are formed to facilitate distributed storage of codewords and iterative decoding of distributed codewords using one or more techniques described herein.

In various implementations, the computing device 600 may be a laptop, a netbook, a notebook, an ultrabook, a smart phone, a tablet, a personal digital assistant (“PDA”), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

System, methods, computer-readable media (transitory and non-transitory), apparatus, devices and other various components may be configured to implement the following. In various embodiments, a first portion of a codeword may be stored on a first die and a second portion of the codeword may be stored on a second die. In various embodiments, an iterative decoder may be configured to iteratively decode the codeword based at least in part on reliability metrics associated with the first and second die.

In various embodiments, the non-volatile memory may be NAND flash memory, FeTRAM, nanowire-based memory, PCM or PCMS. In various embodiments, the reliability metrics may be used to generate soft information for input to the iterative decoder. In various embodiments, the codeword may be a LDPC codeword, and the iterative decoder may be an LDPC decoder. In various embodiments, the reliability metrics associated with the first and second die may be raw bit error rates.

In various embodiments, an iterative decoder may receive m portions of a codeword for use with an error-correcting code from m die of non-volatile memory. In various embodiments, the iterative decoder may iteratively decode the codeword based on the m received portions and m reliability metrics associated with the m die. In various embodiments, m may be equal to 2, 4, 6, 8 and so on. In various embodiments, receiving m portions of the codeword may include reading m portions of the codeword from m die of NAND flash memory.

In various embodiments, the m reliability metrics may be raw bit error rates of the m die. In various embodiments, potential probabilities associated with a first die of the m die may be generated based on a raw bit error rate of the first die of the m die. In various embodiments, magnitudes of the generated potential probabilities may be inversely proportional to the raw bit error rate of the first die of the m die. In various embodiments, a potential probability may be selected from potential probabilities associated with the first die of the m die, based on results of one or more extra read reference supply voltages.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

1-37. (canceled)

38. An apparatus comprising:
non-volatile memory including a first die and a second die;
a read/write logic configured to store a first portion of a codeword for use with an error-correcting code on the first die, and to store a second portion of the codeword on the second die; and
an iterative decoder configured to iteratively decode the codeword based at least in part on reliability metrics associated with the first and second die.

39. The apparatus of claim 38, wherein the non-volatile memory is NAND flash memory.

40. The apparatus of claim 38, wherein the non-volatile memory is ferroelectric random-access memory (“FeTRAM”).

41. The apparatus of claim 38, wherein the non-volatile memory comprises nanowire-based memory.

42. The apparatus of claim 38, wherein the non-volatile memory comprises phase change memory or phase change memory with switch.

43. The apparatus of claim 38, wherein the reliability metrics are used to generate soft information for input to the iterative decoder.

44. The apparatus of claim 38, wherein the codeword is a low-density parity-check codeword.

45. The apparatus of claim 38, wherein the reliability metrics associated with the first and second die are raw bit error rates.

46. The apparatus of claim 38, wherein the non-volatile memory includes a third, fourth, fifth and sixth die, and wherein the memory controller is further configured to store a third portion of the codeword on the third die, to store a fourth portion of the codeword on the fourth die, to store a fifth portion of the codeword on the fifth die, to store a sixth portion of the codeword on the sixth die, and to decode the codeword based at least in part on reliability metrics associated with the third, fourth, fifth and sixth die.

47. A computer-implemented method, comprising:
receiving, by an iterative decoder, m portions of a codeword for use with an error-correcting code from m die of non-volatile memory; and
iteratively decoding, by the iterative decoder, the codeword based on the m received portions and m reliability metrics associated with the m die.

48. The computer-implemented method of claim 47, wherein receiving m portions of the codeword includes reading m portions of the codeword from m die of NAND flash memory.

49. The computer-implemented method of claim 47, further comprising generating soft information, for input to the iterative decoder, using the reliability metrics associated with the m die.

50. The computer-implemented method of claim 49, wherein the iterative decoder is a low-density parity-check decoder.

51. The computer-implemented method of claim 47, wherein the m reliability metrics are raw bit error rates of the m die.

52. The computer-implemented method of claim 51, further comprising generating, by the iterative decoder, potential probabilities associated with a first die of the m die based on a raw bit error rate of the first die of the m die.

53. A system, comprising:
a processor;
non-volatile memory operatively coupled to the processor and including m die with m associated reliability metrics; and
a memory controller to be operated by the processor and configured to distribute m portions of a codeword for use with an error-correcting code among the m die, and to iteratively decode the codeword based at least in part on soft information generated from the m reliability metrics associated with the m die.

54. The system of claim 53, wherein the non-volatile memory is NAND flash memory.

55. The system of claim 53, wherein the codeword is a low-density parity-check codeword.

56. The system of claim 53, wherein the reliability metrics associated with the m die are m raw bit error rates.

57. The system of claim 56, wherein the memory controller is further configured to generate potential probabilities associated with a first die of the m die based on a raw bit error rate of the first of the m die.

58. The system of claim 57, wherein magnitudes of the generated potential probabilities are inversely proportional to the raw bit error rate of the first of the m die.

59. The system of claim 58, wherein the memory controller is further configured to select, from the potential probabilities associated with the first die of the m die, a potential probability based on results of one or more extra read reference supply voltages applied to a cell of the first die.

60. The system of claim 53, wherein the non-volatile memory comprises ferroelectric random-access memory (“FeTRAM”).

61. The system of claim 53, wherein the non-volatile memory comprises nanowire-based memory.

62. The system of claim 53, wherein the non-volatile memory comprises phase change memory or phase change memory with switch.
